(19) United States
(12) Patent Application Publication
(10) Pub. No.: US 2025/0336592 A1
(43) Pub. Date: Oct. 30, 2025

(54) BALUN DESIGN FOR ULTRA HIGH BAND

(71) Applicant: SKYWORKS SOLUTIONS, INC., Irvine, CA (US)

(72) Inventors: Xiaoqiang Li, San Jose, CA (US); Shihan Qin, Fresno, CA (US); Jiunn-Sheng Guo, Eastvale, CA (US); Qi Zeng, Thousand Oaks, CA (US)

(21) Appl. No.: 19/175,340

(22) Filed: Apr. 10, 2025

Related U.S. Application Data
(60) Provisional application No. 63/638,726, filed on Apr. 25, 2024.

(51) Int. Cl. H01F 27/28; H01F 27/00; H03F 1/34

(52) U.S. Cl. CPC H01F 27/2847; H01F 27/006; H03F 1/347; H03F 2200/06

(57) ABSTRACT

Examples of the disclosure include a balun comprising a primary winding disposed in a first plane, the primary winding being characterized by a longitudinal axis and a first outer radial distance extending from the longitudinal axis to an outermost edge of the primary winding, and a secondary winding disposed in a second plane, the secondary winding being characterized by the longitudinal axis and a second outer radial distance extending from the longitudinal axis to an outermost edge of the secondary winding, the first outer radial distance being equal to or greater than the second outer radial distance.

### CROSS-REFERENCE TO RELATED APPLICATIONS

This application claims priority under 35 U.S.C. § 119(e) to U.S. Provisional Application Ser. No. 63/638,726, titled “BALUN DESIGN FOR ULTRA HIGH BAND,” filed on Apr. 25, 2024, which is hereby incorporated by reference in its entirety.

### BACKGROUND

### 1. Field of the Disclosure

At least one example in accordance with the present disclosure relates generally to power amplifiers.

### 2. Discussion of Related Art

Electronic devices, such as mobile cellular devices, may exchange information with other electronic devices. A mobile cellular device may include an antenna to transmit and receive signals. Mobile cellular devices may include additional components and circuitry to process signals transmitted and received via the antenna. For example, a mobile cellular device may include one or more power amplifiers to amplify a signal transmitted or received via the antenna.

### SUMMARY

Examples of the methods and systems discussed herein are not limited in application to the details of construction and the arrangement of components set forth in the following description or illustrated in the accompanying drawings. The methods and systems may be capable of implementation in other embodiments and of being practiced or of being carried out in various ways. Examples of specific implementations are provided herein for illustrative purposes and are not intended to be limiting. Acts, components, elements, and features discussed in connection with any one or more examples may be configured to operate and/or be implemented in a similar role in any other examples.

The phraseology and terminology used herein is for the purpose of description. References to examples, embodiments, components, elements, or acts of the systems and methods herein referred to in the singular may also embrace embodiments including a plurality. Similarly, references in plural to embodiments, components, elements, or acts may be implemented as a singularity. References in the singular or plural form may therefore not be intended to limit the presently disclosed systems or methods, their components, acts, or elements. The use herein of “including,” “comprising,” “having,” “containing,” “involving,” and variations so forth, may encompass the items listed thereafter and equivalents thereof as well as additional items.

References to “or” may be construed as inclusive so that any terms described using “or” may indicate any of a single, more than one, and all of the described terms. For example, the phrase “at least one of A or B” may refer A and/or B-that is, A only, B only, or A and B together. In addition, in the event of inconsistent usages of terms between this document and documents incorporated herein by reference, the term usage in the incorporated documents is supplementary to this document. For irreconcilable differences, the term usage in this document controls.

According to at least one aspect of the present disclosure, a balun is provided comprising a primary winding disposed in a first plane, the primary winding being characterized by a longitudinal axis and a first outer radial distance extending from the longitudinal axis to an outermost edge of the primary winding; and a secondary winding disposed in a second plane, the secondary winding being characterized by the longitudinal axis and a second outer radial distance extending from the longitudinal axis to an outermost edge of the secondary winding, the first outer radial distance being equal to or greater than the second outer radial distance.

In at least one example, the primary winding includes a single turn, and wherein the outermost edge of the primary winding includes an outer edge of the single turn. In at least one example, the secondary winding includes 2.5 turns, and the outermost edge of the secondary winding includes an outermost turn of the secondary winding. In at least one example, the primary winding is further characterized by a first inner radial distance extending from the longitudinal axis to an innermost edge of the primary winding, the secondary winding is further characterized by a second inner radial distance extending from the longitudinal axis to an innermost edge of the secondary winding, and the first inner radial distance is approximately equal to the second inner radial distance.

In at least one example, the first inner radial distance and the second inner radial distance are each approximately 150 um. In at least one example, the first outer radial distance is approximately 400 um. In at least one example, the primary winding includes a single turn having a width of approximately 250 um. In at least one example, the second outer radial distance is approximately 400 um. In at least one example, the primary winding is concentric with the secondary winding. In at least one example, a footprint of the primary winding in the first plane covers a footprint of the secondary winding in the second plane. In at least one example, the first plane is parallel with the second plane. In at least one example, the primary winding includes a single turn having a width of approximately 250 um.

According to at least one aspect of the disclosure, a system is provided comprising a first power amplifier; a second power amplifier; and a balun including a primary winding having a first balanced input connection configured to be coupled to the first power amplifier and a second balanced input connection configured to be coupled to the second power amplifier, the primary winding being characterized by a longitudinal axis and a first outer radial distance extending from the longitudinal axis to an outermost edge of the primary winding, and a secondary winding having an unbalanced output and being characterized by the longitudinal axis and a second outer radial distance extending from the longitudinal axis to an outermost edge of the secondary winding, the first outer radial distance being equal to or greater than the second outer radial distance.

In at least one example, the first balanced input connection of the primary winding is configured to be coupled to the first power amplifier via a first flip-chip connection and the second balanced input connection of the primary winding is configured to be coupled to the second power amplifier via a second flip-chip connection. In at least one example, the primary winding includes a single turn, and wherein the outermost edge of the primary winding includes an outer edge of the single turn. In at least one example, the secondary winding includes 2.5 turns, and wherein the outermost edge of the secondary winding includes an outermost turn of the secondary winding. In at least one example, the primary winding is further characterized by a first inner radial distance extending from the longitudinal axis to an innermost edge of the primary winding, the secondary winding is further characterized by a second inner radial distance extending from the longitudinal axis to an innermost edge of the secondary winding, and the first inner radial distance is approximately equal to the second inner radial distance.

In at least one example, the first inner radial distance and the second inner radial distance are each approximately 150 um. In at least one example, the first outer radial distance is approximately 400 um. In at least one example, the primary winding includes a single turn having a width of approximately 250 um.

### BRIEF DESCRIPTION OF THE DRAWINGS

Various aspects of at least one embodiment are discussed below with reference to the accompanying figures, which may not be drawn to scale. The figures are included to provide an illustration and a further understanding of the various aspects and embodiments, and are incorporated in and constitute a part of this specification, but are not intended as a definition of the limits of any particular embodiment. The drawings, together with the remainder of the specification, serve to explain principles and operations of the described and claimed aspects and embodiments. In the figures, each identical or substantially similar component that is illustrated in various figures may be represented by a like numeral. For purposes of clarity, not every component may be labeled in every figure. In the figures:

FIG. 1 illustrates a block diagram of a wireless device according to an example;

FIG. 2 illustrates a block diagram of a power amplifier according to an example;

FIG. 3 illustrates a schematic view of a balun according to an example;

FIG. 4 illustrates a schematic view of a balun according to another example;

FIG. 5 illustrates a schematic view of a balun according to another example;

FIG. 6 illustrates a schematic view of a balun according to another example;

FIG. 7 illustrates a schematic view of a balun according to another example;

FIG. 8 illustrates a perspective view of a multi-chip module according to an example; and

FIG. 9 illustrates a perspective view of a flip-chip according to an example.

### DETAILED DESCRIPTION

Electrical devices may include power amplifiers. Power amplifiers receive an input signal, amplify the input signal based upon a gain value, and output an amplified output signal based on the input signal and the gain value. Performance of a power amplifier is characterized by various metrics. Example performance metrics may include, amongst others, linearity. In some examples, a power amplifier that is considered “ideal” may exhibit a gain that is constant, that is, does not vary as a magnitude of input power is varied. In this example, the gain may be considered perfectly linear because the gain is constant.

Non-ideal power amplifiers may exhibit a gain that is not linear. For example, the gain of a non-ideal power amplifier may be affected by inductive and/or capacitive effects that vary as a frequency of the amplified signal varies. A power amplifier that has a substantially linear gain at or within a certain operating point or range may be considered to exhibit a favorable performance. Accordingly, linearity performance is one metric of power-amplifier performance.

Non-ideal power amplifiers may not be perfectly efficient due to undesired losses in the power amplifier. For example, some power amplifiers, such as push-pull power amplifiers, may include or be coupled to transformers, such as baluns. Baluns may transform balanced signals to unbalanced signals. Ideal baluns may present a low loadline to the power amplifier for high-linearity performance, including at low voltage biases. However, baluns may have a leakage inductance that adversely impacts linearity of the power amplifier, particularly at low voltage biases.

Increasing a coupling factor of the balun (that is, a coupling factor between the primary winding[s] and the secondary winding[s] of the balun) may improve the performance of the balun. However, increasing the coupling factor of the balun may involve increasing the inductance of the primary winding(s) of the balun. For example, increasing the coupling factor of the balun may involve increasing the radius of the primary winding(s) of the balun. This widening improves the coupling factor, but also increases the inductance of the primary winding(s). Increasing the inductance of the primary winding(s) may adversely impact the performance of the balun by increasing the leakage inductance of the balun and thereby frustrating efforts to obtain a low loadline.

Accordingly, a design tension may exist between improving power-amplifier linearity and decreasing balun losses. Improving a coupling factor of the balun increases balun performance, but improving the coupling factor may be achieved by increasing the radius of the balun primary winding(s). Increasing the radius of the balun primary winding(s) increases the inductance, and therefore the leakage inductance, of the balun. Although balun performance and power-amplifier linearity may be improved, losses may be amplified by the worsened leakage inductance.

Balun performance may also be adversely impacted by a physical coupling between the balun and power amplifiers. For example, a balun may be coupled to at least two power amplifiers via wirebond-type connections to receive balanced signals from the power amplifiers. Inductance from the wirebond may be proportional to signal frequency and, therefore, balun performance may be relatively poor particularly at high frequencies. A ribbon-bond-type connection may improve performance relative to wirebonds, but the improvement may be relatively modest.

Examples provided herein improve balun performance and reduce balun losses. In one example, a width of a conductor making up a balun primary winding is increased. That is, rather than increasing the radius of the primary winding, a width of the primary-winding conductor is increased. The width of the primary-winding conductor may be increased such that the primary winding is wide enough to cover all of the secondary-winding coils. Increasing the primary-winding width increases the coupling factor of the balun while reducing the inductance of the balun, thereby improving balun performance. In some examples, balun performance is further improved by coupling the balun to the power amplifier with a flip-chip-type connection. Flip-chip connections may have minimal or negligible inductance such that balun performance is enhanced, particularly at high frequencies.

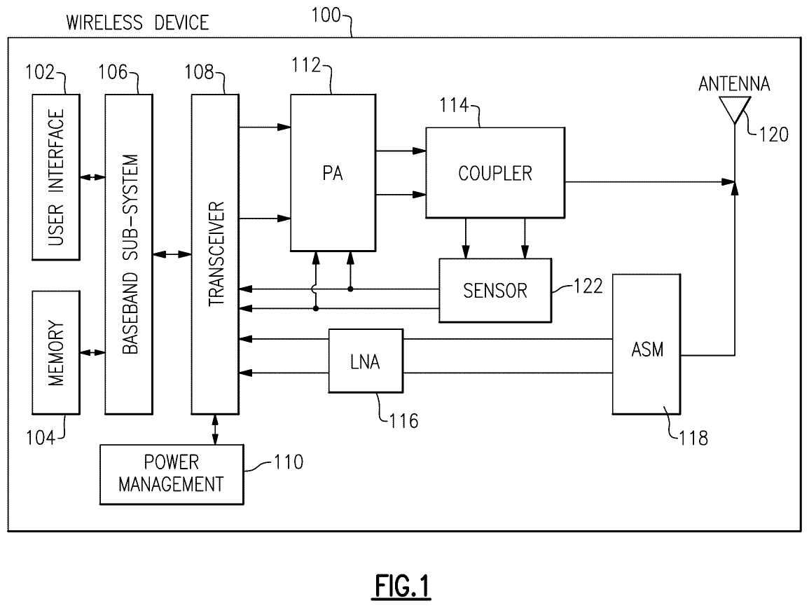

Example power amplifiers may be implemented according to various configurations. For purposes of explanation only, examples are given with respect to push-pull power amplifiers. However, it is to be appreciated that the principles of the disclosure are not limited to push-pull power amplifiers. Furthermore, power amplifiers according to the disclosure may be implemented in any of a variety of electronic devices, such as consumer electronics, automobiles, appliances, laptop computers, desktop computers, industrial equipment, and so forth. For purposes of explanation only, examples may be provided in which power amplifiers are implemented in wireless cellular devices, such as smartphones. For example, an example power amplifier may be implemented in a wireless device as discussed below with respect to FIG. 1.

FIG. 1 illustrates a block diagram of a wireless device 100 according to an example. The wireless device 100 can be a cellular phone, smart phone, tablet, modem, communication network or any other portable or non-portable device configured for voice and/or data communication. The wireless device 100 includes a user interface 102, memory and/or storage 104, a baseband sub-system 106, a transceiver 108, a power-management system 110, a power-amplifier (PA) module 112, a coupler 114, a low-noise amplifier (LNA) 116, a switching circuit 118 (also referred to as an antenna switch module [ASM]), an antenna 120, and at least one sensor 122.

The antenna 120 is configured to transmit and/or receive one or more signals, such that the wireless device 100 may communicate with one or more external devices via the antenna 120. The transceiver 108 is configured to generate signals for transmission and/or to process received signals. In some embodiments, transmission and reception functionalities can be implemented in separate components (for example, a transmit module and a receiving module) or be implemented in the same module.

Signals generated for transmission are provided from the transceiver 108 to the PA module 112, which amplifies the generated signals from the transceiver 108. As will be appreciated by those skilled in the art, the PA module 112 can include one or more power amplifiers. The PA module 112 may also include one or more baluns. For example, a balun may receive balanced, amplified signals from the power amplifiers and transform the balanced signals to an unbalanced signal.

The PA module 112 can be used to amplify a wide variety of radio-frequency (RF) or other frequency-band transmission signals. For example, the PA module 112 can receive an enable signal that can be used to pulse the output of the power amplifier to aid in transmitting a wireless local-area-network (WLAN) signal or any other suitable pulsed signal. The PA module 112 can be configured to amplify any of a variety of types of signal, including, for example, a 5G signal, a Global System for Mobile (GSM) signal, a code-division multiple-access (CDMA) signal, a W-CDMA signal, a Long-Term-Evolution (LTE) signal, or an EDGE signal. In certain embodiments, the PA module 112 and associated components including switches and the like can be fabricated on GaAs substrates using, for example, pHEMT or BiFET transistors, or on a silicon substrate using CMOS transistors. The wireless device 100 also includes the LNA 116, which may include one or more low-noise amplifiers configured to amplify received signals in a similar or different manner as power amplifier(s) of the PA module 112.

The wireless device 100 also includes the switching circuit 118, which is configured to switch between different bands and/or modes. For example, the switching circuit 118 may be configured to couple the LNA 116 to the antenna 120 in a receive mode of operation and to decouple the LNA 116 from the antenna 120 in a transmit mode of operation. Similarly, the PA module 112 is coupled to the antenna 120 such that signals provided to the antenna 120 from the PA module 112 in the transmit mode of operation bypass the receive path (and switching circuit 118) of the wireless device 100. In some examples, the switching circuit 118 may be configured to couple and/or decouple the LNA 116 and/or PA module 112 to one or more of several antennas, which may include the antenna 120.

Accordingly, in certain embodiments the antenna 120 can both receive signals that are provided to the transceiver 108 via the switching circuit 118 and the LNA 116 and also transmit signals from the wireless device 100 via the transceiver 108, the PA module 112, and the coupler 114. However, in other examples multiple antennas can be used for different modes of operation.

The power-management system 110 is connected to the transceiver 108 and is configured to manage the power for the operation of the wireless device 100. The power-management system 110 can also control the operation of the wireless device 100, such as by controlling components of power amplifier(s) of the PA module 112 and/or LNA 116. The power-management system 110 can include, or can be connected to, a battery that supplies power for the various components of the wireless device 100. The power-management system 110 can further include one or more processors or controllers that can control the transmission of signals and can also configure components of the wireless device 100 based upon the frequency of the signals being transmitted or received, for example. In addition, the processor(s) or controller(s) of the power-management system 110 may provide control signals to actuate switches, tune components, or otherwise configure components of the wireless device 100, such as components of the PA module 112 and/or LNA 116, as discussed below. In at least one embodiment, the processor(s) or controller(s) of the power-management system 110 can also provide control signals to control the switching circuit 118 to operate in the transmit or receive mode.

In one embodiment, the baseband sub-system 106 is connected to the user interface 102 to facilitate various input and output of voice and/or data provided to and received from the user. The baseband sub-system 106 can also be connected to the memory and/or storage 104 which is configured to store data and/or instructions to facilitate the operation of the wireless device, and/or to provide storage of information for the user.

The wireless device 100 also includes the coupler 114 having one or more coupler sections for measuring transmitted power signals from the PA module 112 and for providing one or more coupled signals to at least one sensor 122.

The at least one sensor 122 can in turn send information to the transceiver 108, power-management system 110, and/or directly to the PA module 112 and/or LNA 116 as feedback for making adjustments to regulate the power level of the PA module 112 and/or LNA 116. In this way the coupler 114 can be used to boost/decrease the power of a transmission signal having a relatively low/high power. It will be appreciated, however, that the coupler 114 can be used in a variety of other implementations.

For example, in certain embodiments in which the wireless device 100 is a mobile phone having a time division multiple access (TDMA) architecture, the coupler 114 can advantageously manage the amplification of an RF transmitted power signal from the PA module 112 and/or LNA 116. In a mobile phone having a TDMA architecture, such as those found in GSM, CDMA, and W-CDMA systems, the PA module 112 can be used to shift power envelopes up and down within prescribed limits of power versus time. For instance, a particular mobile phone can be assigned a transmission time slot for a particular frequency channel. In this case the PA module 112 and/or LNA 116 can be employed to aid in regulating the power level one or more RF power signals over time, so as to prevent signal interference from transmission during an assigned receive time slot and to reduce power consumption. In such systems, the coupler 114 can be used to measure the power of a power-amplifier output signal to aid in controlling the PA module 112 and/or LNA 116, as discussed above. The implementations shown in FIG. 1 is exemplary and non-limiting. For example, the implementation of FIG. 1 illustrates the coupler 114 being used in conjunction with a transmission of an RF signal, however, various examples of the coupler 114 discussed herein can also be used with received RF signals or other signals as well.

As discussed above, the PA module 112 (and/or LNA 116) may include one or more power amplifiers. For example, at least the PA module 112 may include one or more push-pull power amplifiers configured to receive an RF input signal, amplify the RF input signal, and provide an amplified RF output signal to an output.

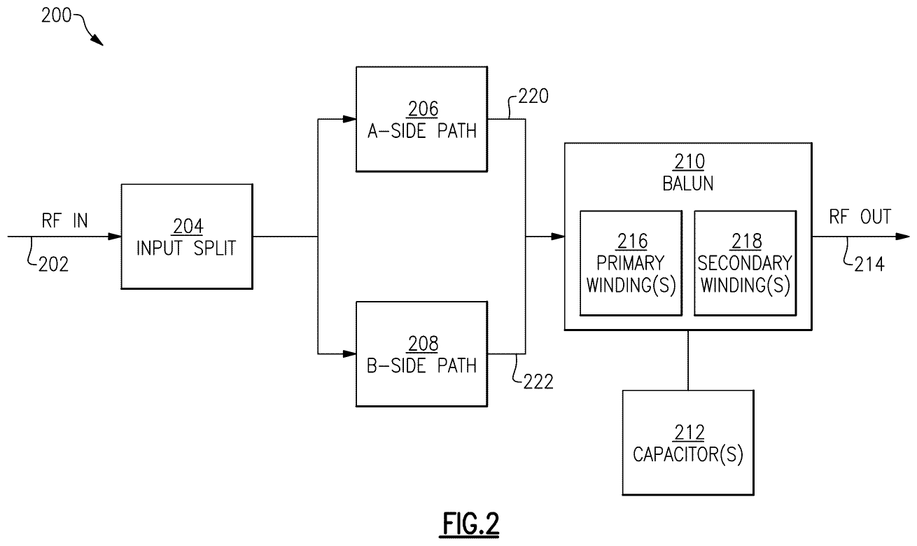

FIG. 2 illustrates a block diagram of at least a portion of a power-amplification (PA) module 200 according to an example. For example, FIG. 2 may illustrate at least a portion of an example of the PA module 112. The PA module 200 includes an RF-signal input 202, an input split 204, an A-side signal path 206, a B-side signal path 208, a balun 210, one or more capacitors 212 (“capacitor 212”), and an RF-signal output 214. The balun 210 includes at least one primary winding 216 (“primary winding 216”) and at least one secondary winding 218 (“secondary winding 218”). The primary winding 216 and the secondary winding 218 may each include coils. Coils may also be referred to as turns; for example, a winding with one coil may be referred to as having a single turn.

The RF-signal input 202 is coupled to the input split 204, and is configured to be coupled to a source of an RF signal, such as the transceiver 108. The input split 204 is coupled to the RF-signal input 202, the A-side signal path 206, and the B-side signal path 208. The A-side signal path 206 is coupled to the input split 204 and to the balun 210. The B-side signal path 208 is coupled to the input split 204 and to the balun 210. The balun 210 is coupled to the A-side signal path 206, the B-side signal path 208, the capacitor 212, and to the RF-signal output 214. The capacitor 212 is coupled to the balun 210. The RF-signal output 214 is coupled to the balun 210, and is configured to be coupled to a component configured to receive an unbalanced, amplified RF signal, such as the coupler 114.

The input split 204 is configured to receive an input signal, split the input signal into two balanced signals, and provide the two balanced signals to the A-side signal path 206 and the B-side signal path 208. Each of the signal paths 206, 208 may include one or more power amplifiers to amplify respective signals. Power amplifiers in the signal paths 206, 208 are configured to amplify respective input signals and transmit the amplified, balanced signals to the balun 210.

For example, the A-side signal path 206 (for example, a power amplifier in the A-side signal path 206) may be coupled to the primary winding 216 via a first connection 220, and the B-side signal path 208 (for example, a power amplifier in the B-side signal path 208) may be coupled to the primary winding 218 via a second connection 222. In some examples, each of the connections 220, 222 include, or are effected by, a flip-chip connection.

The balun 210 is configured to convert the balanced signals to an unbalanced signal, and provide the unbalanced signal to the RF-signal output 214. The capacitor 212 may include one or more capacitive couplings between the balun 210 and other components adjacent to the balun 210. The balun 210 includes the primary winding 216 and the secondary winding 218. The primary winding 216 is configured to receive the two unbalanced signals from the signal paths 206, 208.

The primary winding 216 is inductively coupled to the secondary winding 218. An inductive coupling between the windings 216, 218 may be defined by a coupling factor, where a coupling factor of 1 may refer to a 100% inductive coupling between the windings 216, 218. The primary winding 216 induces a secondary signal in the secondary winding 218 responsive to receiving the balanced signals from the signal paths 206, 208 via the connections 220, 222. The secondary signal may be an unbalanced signal. The secondary winding 218 may then provide the unbalanced signal to the RF output 214.

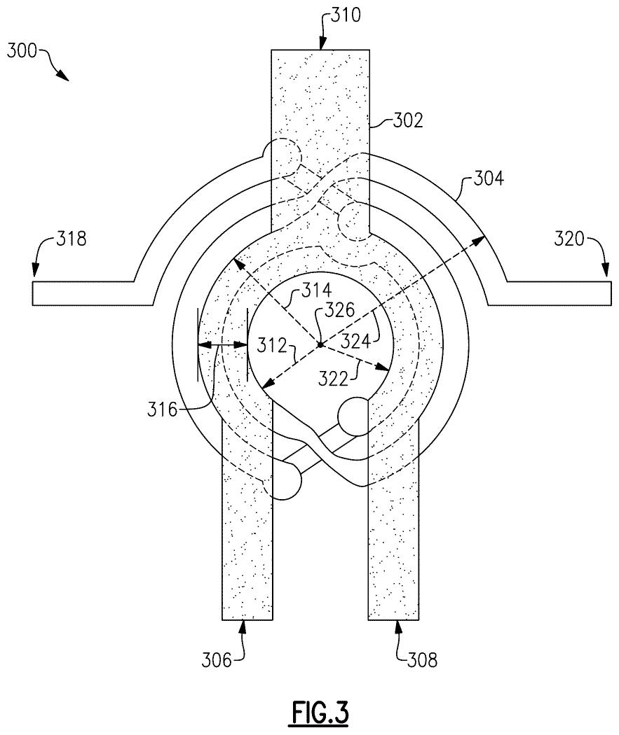

FIG. 3 illustrates a schematic view of a balun 300 according to one example. The balun 300 may be one example of the balun 210. The balun 300 includes a primary winding 302 and a secondary winding 304. The primary winding 302 may be an example of the primary winding 216. The secondary winding 304 may be an example of the secondary winding 218. For purposes of example, the primary winding 302 includes one coil (that is, a single turn) and the secondary winding 304 includes 2.5 coils (that is, 2.5 turns). However, this is an example only, and other numbers of coils may be within the scope of the disclosure. For example, the secondary winding 304 may include one coil, two coils, five coils, 3.5 coils, any number of coils five or fewer, or a different number of coils.

The primary winding 302 includes a first input connection 306, a second input connection 308, and an end connection 310. The primary winding 302 is defined by an inner radius 312, which spans an inner radial distance, and an outer radius 314, which spans an outer radial distance. The secondary winding 304 includes a first output connection 318 and a second output connection 320. The secondary winding 304 is defined by an inner radius 322, which spans an inner radial distance, and an outer radius 324, which spans an outer radial distance. Each of the radii 312, 314, 322, 324 may be determined relative to a longitudinal axis 326 of the balun 300, which extends into the page of FIG. 3. In some examples, the windings 302, 304 may be concentric with each other at the longitudinal axis 326.

The inner radius 312 of the primary winding 302 extends from a longitudinal axis 326 of the primary winding 302 to the inner edge of the single coil of the primary winding 302. The inner edge of the single coil may be the innermost edge of the primary winding 302. The outer radius 314 extends from the longitudinal axis 326 of the primary winding 302 to the outer edge of the single coil of the primary winding 302. The outer edge of the single coil may be the outermost edge of the primary winding 302. The coil of the primary winding 302 therefore has a width 316 defined by a difference between the radii 312, 314.

The inner radius 322 of the secondary winding 304 extends from the longitudinal axis 326 of the secondary winding 304 to the inner edge of the innermost coil of the secondary winding 304. The inner edge of the innermost coil may be the innermost edge of the secondary winding 304. The outer radius 324 extends from the longitudinal axis 326 of the secondary winding 304 to the outer edge of the outermost turn or coil (or partial coil, such as a half-coil) of the secondary winding 304. The outer edge of the outermost coil (or partial coil) may be the outermost edge of the secondary winding 304.

In at least one example, the inner radii 312, 322 may be equal to one another. For example, the inner radii 312, 322 may be approximately 150 um. The outer radius 314 of the primary winding 302 may be approximately 250 um, such that the width 316 is approximately 100 um. The outer radius 324 of the secondary winding 304 may be approximately 400 um. As discussed above, the windings 302, 304 may be concentric with each other, with the center being the longitudinal axis 326. Thus, the windings 302, 304 may be disposed in parallel planes that are normal to the longitudinal axis 326. The primary winding 302 may be disposed in a first plane that intersects the longitudinal axis 326 at a first location along the longitudinal axis 326, and the secondary winding 302 may be disposed in a second plane that intersects the longitudinal axis 326 at a second location along the longitudinal axis 326. The two parallel planes may therefore be offset from each other along the longitudinal axis 326.

The input connections 306, 308 of the primary winding 302 are configured to be coupled to, and receive balanced signals from, power amplifiers in the input-signal paths 206, 208 via the connections 220, 222. For example, the first input connection 306 of the primary winding 302 may be coupled to the first input connection 220 of the A-side signal path 206 to receive a first balanced signal from a first power amplifier, and the second input connection 308 of the primary winding 302 may be coupled to the second input connection 220 of the B-side signal path 208 to receive a second balanced signal from a second power amplifier, via a flip-chip connection. Accordingly, the input connections 306, 308 may be referred to as balanced input connections in some examples. The end connection 310 of the primary winding 302 may be capacitively coupled to a terminal pin to terminate the primary winding 302.

The first output connection 318 may be coupled to a signal-output connection, such as the RF output 214. The second output connection 320 may be coupled to a reference node, such as a ground node. Balanced signals received by the primary winding 302 at the input connections 306, 308 may induce a secondary, unbalanced signal in the secondary winding 304, which may be provided to the RF output 214 via the first output connection 318. The first output connection 318 may therefore be referred to as an unbalanced output 318.

As illustrated in FIG. 3, the inner radii 312, 322 of the windings 302, 304, respectively, may be approximately equal, but the outer radius 314 of the primary winding 302 may be less than the outer radius 324 of the secondary winding 304. Accordingly, a footprint of the primary winding 302 (that is, the area covered by the primary winding 302 from the perspective of FIG. 3 in a plane normal to the longitudinal axis 326) may not completely cover a footprint of the secondary winding 304 (that is, the area covered by the secondary winding 304 from the perspective of FIG. 3 in a plane normal to the longitudinal axis 326).

A coupling factor between the windings 302, 304 may be relatively low in the example of FIG. 3, because the footprint of the primary winding 302 covers only a small portion of the footprint of the secondary winding 304. In the following examples, the footprint of the primary winding 302 may be expanded by increasing the outer radius 314 of the primary winding 302 without changing the inner radius 312 of the primary winding 302. At least because the inner radius 312 of the primary winding 302 is held constant, the radius of the primary winding 302 as a whole does not change, and thus the inductance of the primary winding 302 is not increased. Furthermore, because the outer radius 314 of the primary winding 302 is increased, the inductance of the primary winding 302 may be reduced without adversely impacting performance of the balun 210. Accordingly, performance of the balun 210 in various example implementations may be improved at least in part by increasing the width 316 of the primary winding 302 without changing the radius of the primary winding 302.

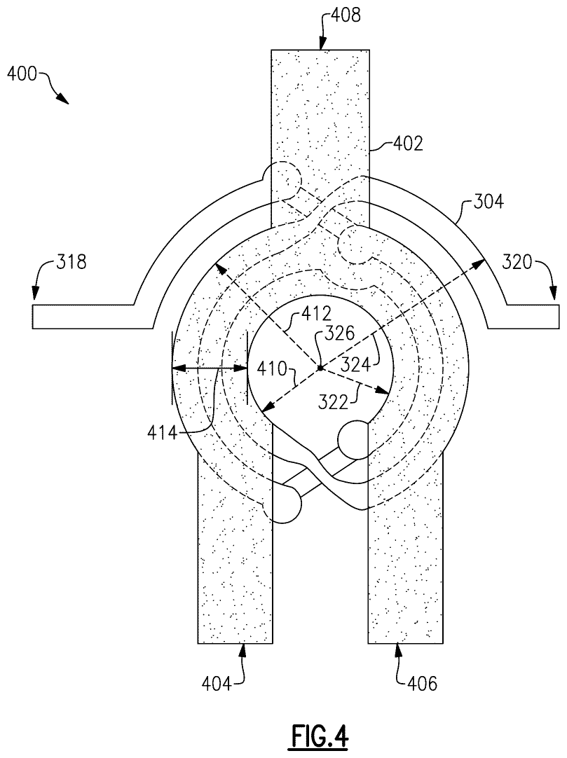

FIG. 4 illustrates a schematic view of a balun 400 according to another example. The balun 400 may be another example of the balun 210. The balun 400 is similar to the balun 300 of FIG. 3, and like components are labeled accordingly. For example, the balun 400 includes the secondary winding 304, which may be implemented substantially the same in the balun 400 as in the balun 300. The balun 400 further includes a primary winding 402. The primary winding 402 may be an implementation of the primary winding 216, but may differ from the primary winding 302.

The primary winding 402 includes a first input connection 404, a second input connection 406, and an end connection 408, each of which may have similar functionality as the connections 306, 308, 310, respectively. The primary winding 402 is defined by an inner radius 410 and an outer radius 412. The inner radius 410 extends from the longitudinal axis 326 of the primary winding 402, which may be concentric with the secondary winding 304, to the inner edge of the single coil of the primary winding 402. The inner edge of the single coil may be the innermost edge of the primary winding 402. The outer radius 412 extends from the longitudinal axis 326 of the primary winding 402 to the outer edge of the single coil of the primary winding 402. The outer edge of the single coil may be the outermost edge of the primary winding 402. The coil of the primary winding 402 therefore has a width 414 defined by a difference between the radii 410, 412.

The inner radius 410 of the primary winding 402 may be substantially the same as the inner radius 312 of the primary winding 302. For example, the inner radius 410 may be approximately 150 um. However, the outer radius 412 of the primary winding 402 may be larger than the outer radius 314 of the primary winding 302. For example, the outer radius 412 of the primary winding 402 may be approximately 300 um, such that the width 414 of the primary winding 402 is approximately 150 um.

The coupling factor of the balun 400 may be higher than the coupling factor of the balun 300 at least because the width 414 of the primary winding 402 is greater than the width 316 of the primary winding 302, thereby increasing the footprint of the primary winding 402. An inductance, and therefore a leakage inductance, of the balun 400 may be reduced relative to the balun 300 by virtue of the increased width 414 of the primary winding 402. Furthermore, the radius of the balun 300 may be approximately the same as the radius of the balun 400, because the inner radius 410 may be approximately the same as the inner radius 312 of the balun 300.

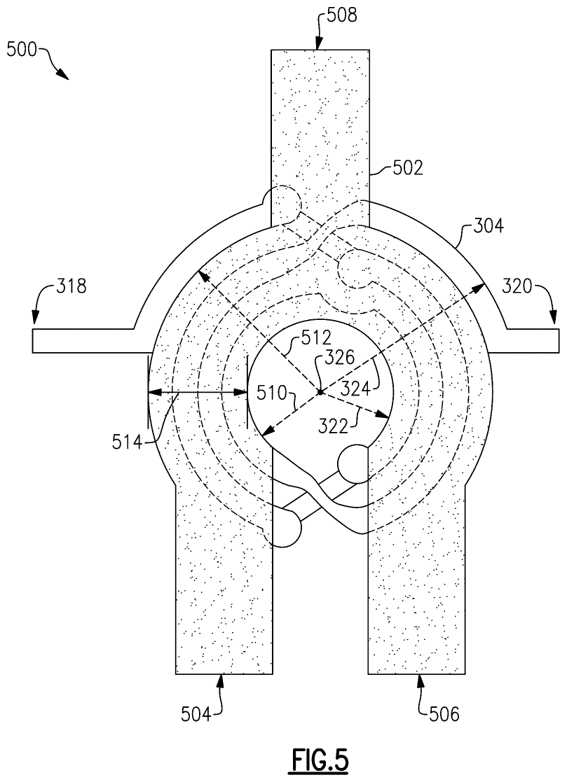

Increasing a primary-winding width of the balun 210 may further increase the performance of the balun 210. FIG. 5 illustrates a schematic view of a balun 500 according to another example. The balun 500 may be another example of the balun 210. The balun 500 is similar to the balun 300 of FIG. 3, and like components are labeled accordingly. For example, the balun 500 includes the secondary winding 304, which may be implemented substantially the same in the balun 500 as in the balun 300. The balun 500 further includes a primary winding 502. The primary winding 502 may be an implementation of the primary winding 216, but may differ from the primary winding 302.

The primary winding 502 includes a first input connection 504, a second input connection 506, and an end connection 508, each of which may have similar functionality as the connections 306, 308, 310, respectively. The primary winding 502 is defined by an inner radius 510 and an outer radius 512. The inner radius 510 extends from the longitudinal axis 326 of the primary winding 502, which may be concentric with the secondary winding 304, to the inner edge of the single coil of the primary winding 502. The inner edge of the single coil may be the innermost edge of the primary winding 502. The outer radius 512 extends from the longitudinal axis 326 of the primary winding 502 to the outer edge of the single coil of the primary winding 502. The outer edge of the single coil may be the outermost edge of the primary winding 502. The coil of the primary winding 502 therefore has a width 514 defined by a difference between the radii 510, 512.

The inner radius 510 of the primary winding 502 may be substantially the same as the inner radius 312 of the primary winding 302. For example, the inner radius 510 may be approximately 150 um. However, the outer radius 512 of the primary winding 502 may be larger than the outer radius 314 of the primary winding 302. For example, the outer radius 512 of the primary winding 502 may be approximately 350 um, such that the width 514 of the primary winding 502 is approximately 200 um.

The coupling factor of the balun 500 may be higher than the coupling factor of the balun 300 and the balun 400 at least because the width 514 of the primary winding 502 is greater than the width 316 of the primary winding 302 and the width 414 of the primary winding 402, thereby increasing the footprint of the primary winding 502. An inductance, and therefore a leakage inductance, of the balun 500 may be reduced relative to the balun 300 and the balun 400 by virtue of the increased width 514 of the primary winding 502. Furthermore, the radius of the balun 300 may be approximately the same as the radius of the balun 500, because the inner radius 510 may be approximately the same as the inner radius 312 of the balun 300.

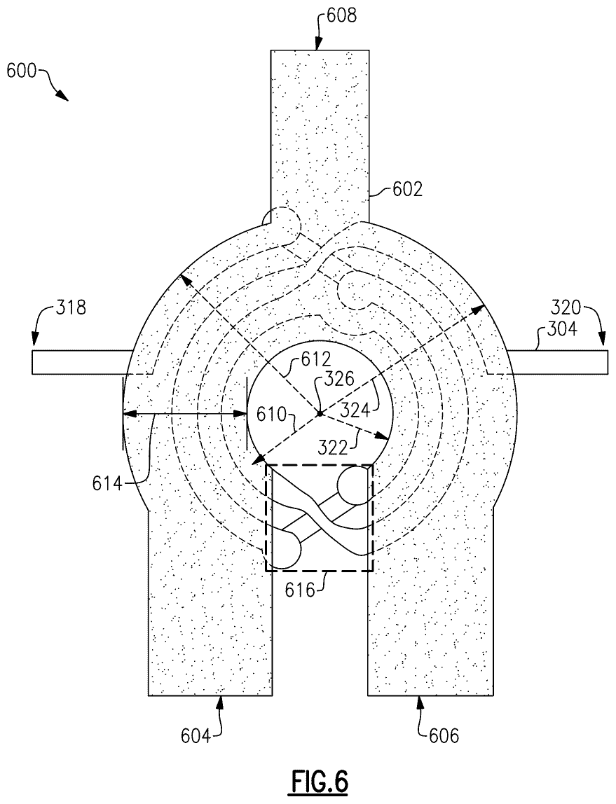

Increasing a primary-winding width of the balun 210 may increase the performance of the balun 210 at least until a footprint of the primary winding 216 substantially completely covers a footprint of the secondary winding 218. FIG. 6 illustrates a schematic view of a balun 600 according to another example. The balun 600 may be another example of the balun 210. The balun 600 is similar to the balun 300 of FIG. 3, and like components are labeled accordingly. For example, the balun 600 includes the secondary winding 304, which may be implemented substantially the same in the balun 600 as in the balun 300. The balun 600 further includes a primary winding 602. The primary winding 602 may be an implementation of the primary winding 216, but may differ from the primary winding 302.

The primary winding 602 includes a first input connection 604, a second input connection 606, and an end connection 608, each of which may have similar functionality as the connections 306, 308, 310, respectively. Accordingly, the input connections 604, 606 may be referred to as balanced input connections 604, 606 in some examples. The primary winding 602 is defined by an inner radius 610 and an outer radius 612. The inner radius 610 extends from the longitudinal axis 326 of the primary winding 602, which may be concentric with the secondary winding 304, to the inner edge of the single coil of the primary winding 602. The inner edge of the single coil may be the innermost edge of the primary winding 602. The outer radius 612 extends from the longitudinal axis 326 of the primary winding 602 to the outer edge of the single coil of the primary winding 602. The outer edge of the single coil may be the outermost edge of the primary winding 602. The coil of the primary winding 602 therefore has a width 614 defined by a difference between the radii 610, 612.

The inner radius 610 of the primary winding 602 may be substantially the same as the inner radius 312 of the primary winding 302, for example, approximately 150 um. However, the outer radius 612 of the primary winding 602 may be larger than the outer radius 314 of the primary winding 302. For example, the outer radius 612 of the primary winding 602 may be approximately equal to the outer radius 324 of the secondary winding 304. In various examples, the outer radius 612 of the primary winding 602 (and the outer radius 324 of an example of the secondary winding 304) may be approximately 400 um. Accordingly, the width 614 of the primary winding 602 may be approximately 250 um.

The coupling factor of the balun 600 may be higher than the coupling factor of the baluns 300, 400, 500 at least because the width 614 of the primary winding 602 is greater than the widths 316, 414, 514 of the primary windings 302, 402, 502, respectively, thereby increasing the footprint of the primary winding 602. An inductance, and therefore a leakage inductance, of the balun 600 may be reduced relative to the baluns 300, 400, 500 by virtue of the increased width 614 of the primary winding 602. Furthermore, the radius of the balun 300 may be substantially the same as the radius of the balun 600, because the inner radius 610 may be substantially the same as the inner radius 312 of the balun 300.

As illustrated in FIG. 6, the footprint of the primary winding 602 largely covers the footprint of the secondary winding 304. The footprint of the primary winding 602 may refer to the area covered by the primary winding 602 in the plane that is normal to the longitudinal axis 326, and similarly for the secondary winding 304. The footprint of the primary winding 602 covers the footprint of the secondary winding 304 except in a region 616 between the two balanced input connections 604, 606. Moreover, the footprint of the primary winding 602 may not extend beyond the footprint of the secondary winding 304, for example, because the outer radius 612 of the primary winding 602 is approximately equal to the outer radius 324 of the secondary winding 304.

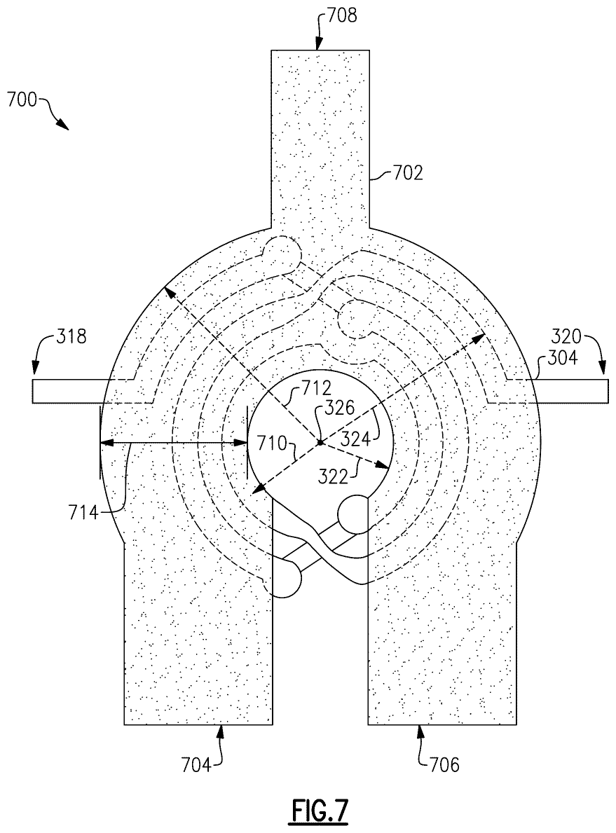

In some examples, the footprint of the primary winding 216 may extend beyond the footprint of the secondary winding 218. FIG. 7 illustrates a schematic view of a balun 700 according to another example. The balun 700 may be another example of the balun 210. The balun 700 is similar to the balun 300 of FIG. 3, and like components are labeled accordingly. For example, the balun 700 includes the secondary winding 304, which may be implemented substantially the same in the balun 700 as in the balun 300. The balun 700 further includes a primary winding 702. The primary winding 702 may be an implementation of the primary winding 216, but may differ from the primary winding 302.

The primary winding 702 includes a first input connection 704, a second input connection 706, and an end connection 708, each of which may have similar functionality as the connections 306, 308, 310, respectively. The primary winding 702 is defined by an inner radius 710, which spans an inner radial distance, and an outer radius 712, which spans an outer radial distance. The inner radius 710 extends from the longitudinal axis 326 of the primary winding 702, which may be concentric with the secondary winding 304, to the inner edge of the single coil of the primary winding 702. The inner edge of the single coil may be the innermost edge of the primary winding 702. The outer radius 712 extends from the longitudinal axis 326 of the primary winding 702 to the outer edge of the single coil of the primary winding 702. The outer edge of the single coil may be the outermost edge of the primary winding 702. The coil of the primary winding 702 therefore has a width 714 defined by a difference between the radii 710, 712.

The inner radius 710 of the primary winding 702 may be substantially the same as the inner radius 312 of the primary winding 302. For example, the inner radius 710 may be approximately 150 um. However, the outer radius 712 of the primary winding 702 may be larger than the outer radius 314 of the primary winding 302 and larger than the outer radius 324 of the secondary winding 304. In various examples, the outer radius 712 of the primary winding 702 may be approximately 450 um, such that the width 714 of the primary winding 702 is approximately 300 um.

The coupling factor of the balun 700 may be higher than the coupling factor of the baluns 300, 400, 500 at least because the width 714 of the primary winding 702 is greater than the widths 316, 414, 514 of the primary windings 302, 402, 502, thereby increasing the footprint of the primary winding 702. An inductance, and therefore a leakage inductance, of the balun 700 may be reduced relative to the baluns 300, 400, 500 by virtue of the increased width 714 of the primary winding 702. Furthermore, the radius of the balun 300 may be substantially the same as the radius of the balun 700, because the inner radius 710 may be substantially the same as the inner radius 312 of the balun 300.

The coupling factor of the balun 700 may also be higher than the coupling factor of the balun 600. However, increases in coupling factor may yield diminishing returns after the outer radius of the primary winding 216 exceeds the outer radius of the secondary winding 218, that is, after the footprint of the primary winding 216 already covers the footprint of the secondary winding 218.

In various examples discussed herein, example values of dimensions have been provided in, for example, microns. Values provided as being approximately a certain number of microns may include values within values +/−0.1 um of a given value, or within +/−1 um of a given value, or within +/−2 um of a given value, or within +/−10 um of a given value, or within +/−1% of a given value, or within +/−5% of a given value, and so forth. For example, as discussed above, although the example value for the inner radii 312, 322 of approximately 150 um is only one non-limiting example, the inner radii 312, 322 having a value of approximately 150 um may include 150 um +/−0.1 um, or 150 um +/−1% (that is, 1.5 um), or 150 um +/−1 um, and so forth.

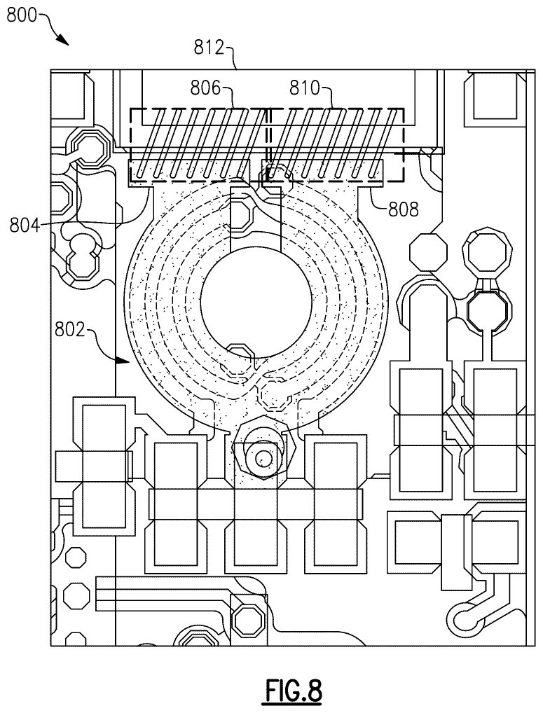

FIG. 8 illustrates a perspective view of a multi-chip module (MCM) 800 according to an example. The MCM 800 may include an example of the PA module 200. The MCM 800 includes a balun 802, which may be an example of the balun 210. The balun 802 includes a first input connection 804 coupled to a first group of wirebond connections 806, and a second input connection 808 coupled to a second group of wirebond connections 810. The balun 802 may receive balanced signals from at least two power amplifiers at the input connections 804, 808 via the wirebond connections 806, 810. For example, the MCM 800 may include a chip 812 including two or more power amplifiers configured to deliver amplified, balanced signals to the balun 802 via the wirebond connections 806, 810.

As discussed above, wirebond-type connections like the wirebond connections 806, 810 may introduce a relatively high amount of leakage inductance. For example, the wirebond connections 806, 810 may introduce up to approximately 0.11 nH. In various examples, the wirebond connections 806, 810 may be removed and replaced with flip-chip-type connections.

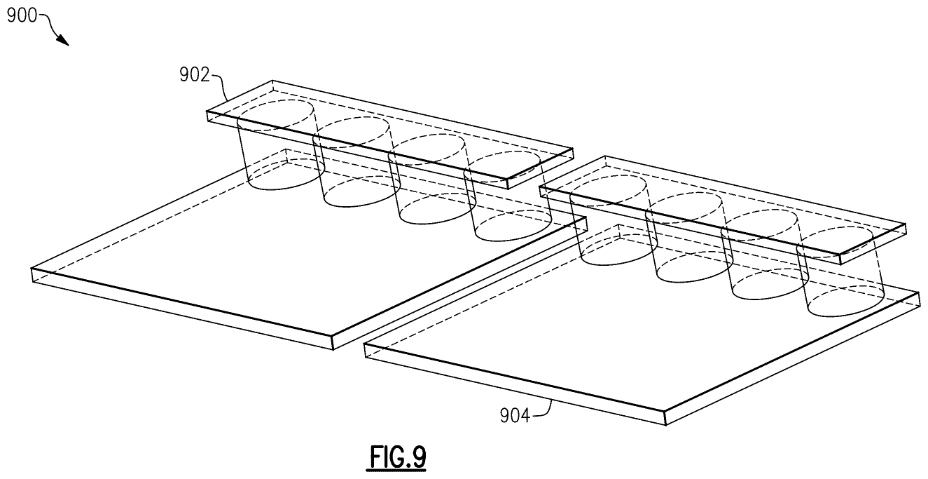

FIG. 9 illustrates a perspective view of a flip-chip 900 according to an example. The flip-chip 900 includes a first flip-chip connector 902 and a second flip-chip connector 904, which may replace the wirebond connections 806, 810 to couple the balun 802 (or a different example of the balun 210) to power amplifiers. The flip-chip connectors 902, 904 may include or be coupled to respective balls of solder or other conductors to establish a physical and/or electrical connection with balanced input connections of the balun 802. The flip-chip 900 may yield substantially reduced leakage inductance in the balun 210 as compared to the wirebond connections 806, 810. For example, whereas the wirebond connections 806, 810 may introduce up to approximately 0.11 nH of leakage inductance, the flip-chip connectors 902, 904 may only introduce up to approximately 0.01 nH of leakage inductance.

Having thus described several aspects of at least one embodiment, it is to be appreciated various alterations, modifications, and improvements will readily occur to those skilled in the art. Such alterations, modifications, and improvements are intended to be part of, and within the spirit and scope of, this disclosure. Accordingly, the foregoing description and drawings are by way of example only.

1. A balun comprising:
a primary winding disposed in a first plane, the primary winding being characterized by a longitudinal axis and a first outer radial distance extending from the longitudinal axis to an outermost edge of the primary winding; and
a secondary winding disposed in a second plane, the secondary winding being characterized by the longitudinal axis and a second outer radial distance extending from the longitudinal axis to an outermost edge of the secondary winding,
the first outer radial distance being equal to or greater than the second outer radial distance.

2. The balun of claim 1 wherein the primary winding includes a single turn, and wherein the outermost edge of the primary winding includes an outer edge of the single turn.

3. The balun of claim 1 wherein the secondary winding includes 2.5 turns, and wherein the outermost edge of the secondary winding includes an outermost turn of the secondary winding.

4. The balun of claim 1 wherein
the primary winding is further characterized by a first inner radial distance extending from the longitudinal axis to an innermost edge of the primary winding,
the secondary winding is further characterized by a second inner radial distance extending from the longitudinal axis to an innermost edge of the secondary winding,
and the first inner radial distance is approximately equal to the second inner radial distance.

5. The balun of claim 4 wherein the first inner radial distance and the second inner radial distance are each approximately 150 um.

6. The balun of claim 5 wherein the first outer radial distance is approximately 400 um.

7. The balun of claim 6 wherein the primary winding includes a single turn having a width of approximately 250 um.

8. The balun of claim 6 wherein the second outer radial distance is approximately 400 um.

9. The balun of claim 1 wherein the primary winding is concentric with the secondary winding.

10. The balun of claim 1 wherein a footprint of the primary winding in the first plane covers a footprint of the secondary winding in the second plane.

11. The balun of claim 1 wherein the first plane is parallel with the second plane.

12. The balun of claim 1 wherein the primary winding includes a single turn having a width of approximately 250 um.

13. A system comprising:
a first power amplifier;
a second power amplifier; and
a balun including
a primary winding having a first balanced input connection configured to be coupled to the first power amplifier and a second balanced input connection configured to be coupled to the second power amplifier, the primary winding being characterized by a longitudinal axis and a first outer radial distance extending from the longitudinal axis to an outermost edge of the primary winding, and
a secondary winding having an unbalanced output and being characterized by the longitudinal axis and a second outer radial distance extending from the longitudinal axis to an outermost edge of the secondary winding,
the first outer radial distance being equal to or greater than the second outer radial distance.

14. The system of claim 13 wherein the first balanced input connection of the primary winding is configured to be coupled to the first power amplifier via a first flip-chip connection and the second balanced input connection of the primary winding is configured to be coupled to the second power amplifier via a second flip-chip connection.

15. The system of claim 13 wherein the primary winding includes a single turn, and wherein the outermost edge of the primary winding includes an outer edge of the single turn.

16. The system of claim 13 wherein the secondary winding includes 2.5 turns, and wherein the outermost edge of the secondary winding includes an outermost turn of the secondary winding.

17. The system of claim 13 wherein
the primary winding is further characterized by a first inner radial distance extending from the longitudinal axis to an innermost edge of the primary winding,
the secondary winding is further characterized by a second inner radial distance extending from the longitudinal axis to an innermost edge of the secondary winding,
and the first inner radial distance is approximately equal to the second inner radial distance.

18. The system of claim 17 wherein the first inner radial distance and the second inner radial distance are each approximately 150 um.

19. The system of claim 18 wherein the first outer radial distance is approximately 400 um.

20. The system of claim 19 wherein the primary winding includes a single turn having a width of approximately 250 um.
